(19) United States
(12) Patent Application Publication
(10) Pub. No.: US 2013/0082728 A1
(43) Pub. Date: Apr. 4, 2013

(54) CIRCUIT-TEST PROBE CARD AND PROBE SUBSTRATE STRUCTURE THEREOF

(71) Applicant: Ching-Dong WANG, Hsinchu City (TW)

(72) Inventor: Ching-Dong WANG, Hsinchu City (TW)

(21) Appl. No.: 13/311,999

(22) Filed: Dec. 6, 2011

(30) Foreign Application Priority Data
Sep. 30, 2011 (TW) 100135562

(51) Int. Cl. G01R 1/067

(52) U.S. Cl. 324/755.01; 324/756.03

(57) ABSTRACT

A circuit-test probe card and a probe substrate structure thereof are disclosed herein to effectively narrow down the pitch of testing points of the circuit-test probe card. The circuit-test probe card utilizes the top and bottom surfaces of the probe substrate to respectively electrically connect with a circuit board and a plurality of probes. The probe substrate includes a main body having a plurality of upper contacts arranged on an upper surface thereof; and a plurality of wires penetrating the main body. Two ends of each wire are respectively exposed on the upper surface and a lower surface of the main body. The pitch of the wires exposed on the upper surface is larger than the pitch of the wires exposed on the lower surface. The wires are respectively electrically connected with the upper contacts.

### BACKGROUND OF THE INVENTION

1. Field of the Invention

The present invention relates to an IC test device, particularly to a circuit-test probe card and a probe substrate structure thereof.

2. Description of the Related Art

Referring to FIG. 1, a conventional probe card comprises a circuit board 100, a probe substrate 110, a probe holder 120 and a plurality of probes 130. The conventional probe card may further comprise a fixing ring 140 and a reinforcing pad 150 respectively arranged on two sides of the circuit board 100 to prevent the circuit board 100 from being distorted by external force or high temperature. The probe substrate 110 is arranged in the hollowed interior of the fixing ring 140. There are a plurality of solder balls 112 arranged one side of the probe substrate 110 and respectively corresponding to contacts 102 of the circuit board 100. The solder balls 112 may be joined to the contacts 102 via a reflow process. There are a plurality of internal contacts 114 arranged on the other side of the probe substrate 110. A plurality of wires of the probe substrate 110 are electrically interconnected with the internal contacts 114 and the solder balls 112.

The probe holder 120 is fixed to the other side of the fixing ring 140. One end of each probe 130 passes through one of upper positioning holes of the probe holder 120 and protrudes from the probe holder 120 by an appropriate length sufficient to reach the internal contact 114. The other end of each probe 130 passes through one of lower through-holes to extend outwards and possesses appropriate elasticity to implement electric contact with a test point of an external circuit.

Since electronic products are growing miniature and multifunctional, the pitch between test points of IC becomes smaller and smaller. Therefore, how to fabricate probe cards with a reduced pitch has become an important subject.

### SUMMARY OF THE INVENTION

One objective of the present invention is to provide a circuit-test probe card and a probe substrate structure to effectively narrow down the pitch of testing points of the circuit-test probe card.

In one embodiment, the probe substrate of the present invention comprises a main body having a plurality of upper contacts on an upper surface thereof; and a plurality of wires penetrating the main body. Two ends of each wire are respectively exposed on the upper surface and a lower surface of the main body. The pitch of the wires exposed on the upper surface is greater than the pitch of the wires exposed on the lower surface. The wires are respectively electrically connected with the upper contacts.

In another embodiment, the probe substrate of the present invention comprises a main body being plate-shaped and having a hollowed interior; and a plurality of wires. A plurality of upper contacts and upper openings is arranged on an upper surface of the main body. A plurality of lower openings are arranged on a lower surface of the main body. The pitch of the upper openings is greater than the pitch of the lower openings. Two ends of each wire respectively pass through the upper opening and the lower opening. The wires are electrically insulated mutually. Each of the wires protrudes from one upper opening and is electrically connected with one of the upper contacts adjacent to the upper opening.

In a further embodiment, the circuit-test probe card of the present invention utilizes the top surface and the bottom surface of a probe substrate to respectively electrically connect with a circuit board and a plurality of probes. The circuit-test probe card is characterized in that the probe substrate includes a main body having a plurality of upper contacts on an upper surface thereof; and a plurality of wires penetrating the main body. Two ends of each wire are respectively exposed on the upper surface and a lower surface of the main body. The pitch of the wires exposed on the upper surface is greater than the pitch of the wires exposed on the lower surface. The wires are respectively electrically connected with the upper contacts.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1 schematically shows a conventional circuit-test probe card;

FIG. 2 schematically shows a probe substrate according to one embodiment of the present invention;

FIG. 3A and FIG. 3B schematically show a probe substrate according to one embodiment of the present invention;

FIG. 4A and FIG. 4B respectively perspective views showing the upper surface and the lower surface of a main body according to one embodiment of the present invention;

FIG. 5A and FIG. 5B schematically show a probe substrate according to one embodiment of the present invention;

FIG. 6A, FIG. 6B, FIG. 6C and FIG. 6D schematically show a probe substrate according to one embodiment of the present invention; and

FIG. 7A and FIG. 7B schematically show a circuit-test probe card according to one embodiment of the present invention.

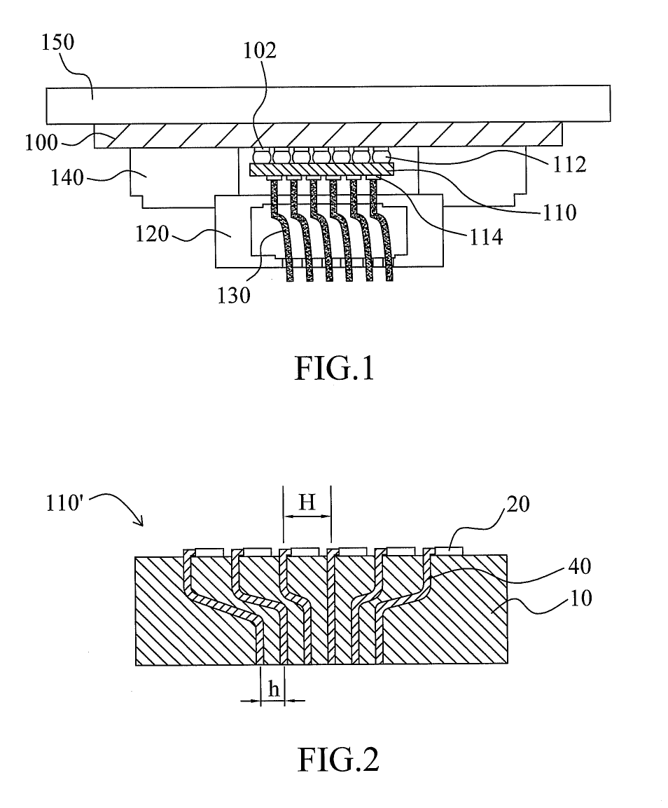

### DETAILED DESCRIPTION OF THE INVENTION

Below, the technical contents of the present invention will be described in detail with embodiments. However, the embodiments are only to exemplify the present invention but not to limit the scope of the present invention.

Referring to FIG. 2, a diagram schematically shows a probe substrate according to one embodiment of the present invention. The probe substrate 110′ includes a main body 10 and a plurality of wires 40 penetrating the main body 10. Two ends of each wire 40 are respectively exposed on an upper surface and a lower surface of the main body 10. The upper surface of the main body 10 has a plurality of upper contacts 20 respectively electrically connected with the wires 40. The pitch H of the wires 40 exposed on the upper surface is greater than the pitch h of the wires 40 exposed on the lower surface.

Following the above description, in the embodiment, the wires 40 protrude from the upper surface to electrically connect with the upper contacts 20. The upper contacts 20 may be solder pads, as shown in FIG. 2. However, the protruding of wires 40 from the upper surface is not a must, as illustrated in another embodiment. The upper contacts 20 may be directly arranged on the positions where the wires 40 are exposed on the upper surface of the main body 10. For example, the upper contacts 20 may be formed by electroplating at the positions on the upper surface where the wires 40 are exposed.

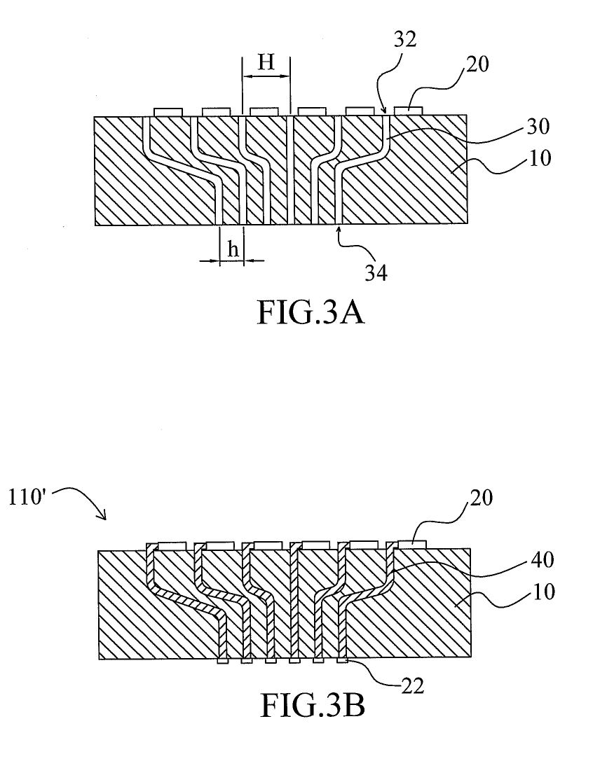

Referring to FIG. 3A and FIG. 3B, in one embodiment, the main body 10 has a plurality of through-holes 30 penetrating the main body 10 from the lower surface to the upper surface to form a plurality of upper openings 32 and a plurality of lower openings 34. The wires 40 are respectively inserted through the through-holes 30. The pitch of the upper openings 32 is greater than the pitch of the lower openings 34.

In one embodiment, a plurality of lower contacts 22 are arranged on the lower surface of the main body 10 and electrically connected with the wires 40. For example, the lower contacts 22 are formed by electroplating at the positions on the lower surface where the wires 40 are exposed.

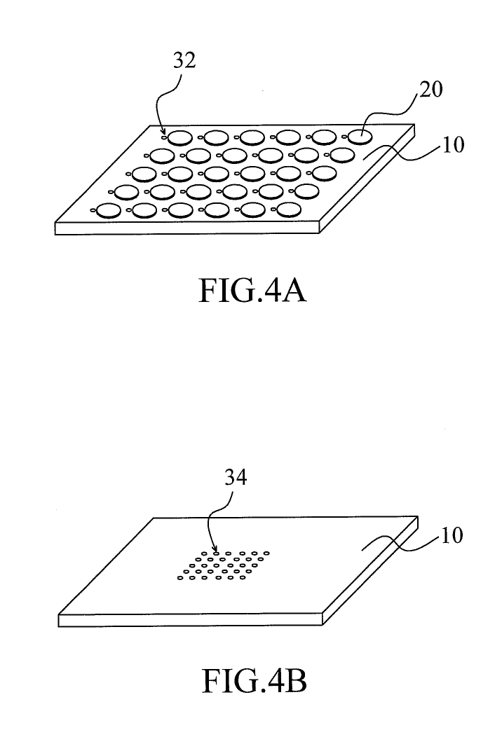

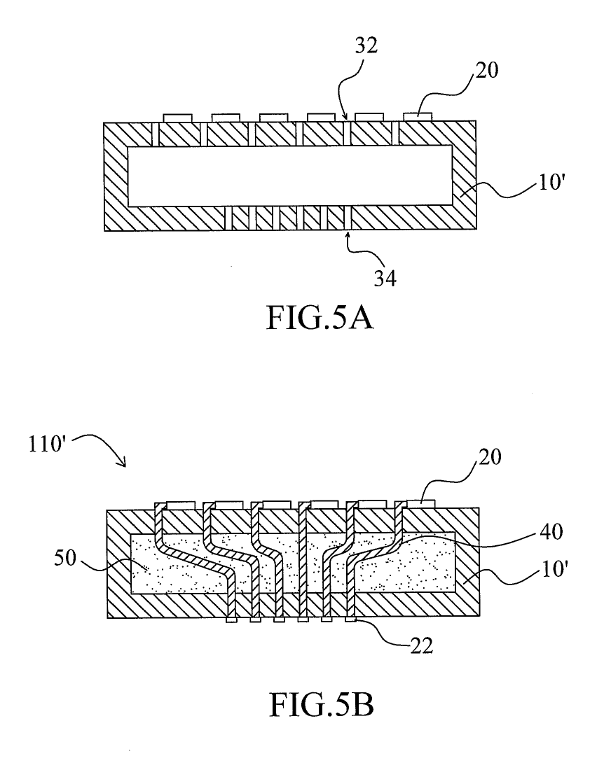

FIG. 4A and FIG. 4B are respectively perspective views showing the upper surface and the lower surface of the main body according to one embodiment of the present invention. The upper surface of the main body 10 is configured for electrically connecting with a circuit board of a circuit-test probe card. Therefore, the upper contacts 20 are arranged corresponding to contacts of the circuit board. The upper openings 32 of the main body 10 are arranged beside the upper contacts 20. The pitch of the lower openings 34 is substantially smaller than the pitch of the upper openings 32, as shown in FIG. 4B.

Referring to FIG. 5A and FIG. 5B, in one embodiment, the probe substrate 110′ includes a plate-shaped main body 10′ and a plurality of wires 40. The plate-shaped main body 10′ is hollow and includes a plurality of upper contacts 20 and upper openings 32 both arranged on the upper surface. The plate-shaped main body 10′ also includes a plurality of lower openings 34 arranged on the lower surface.

Further, two ends of each wire 40 respectively pass through the upper opening 32 and the lower opening 34. The pitch of the upper openings 32 is greater than the pitch of the lower openings 34. Each wire 34 protrudes from the upper opening 32 and is electrically connected with one of the adjacent upper contacts 20. In the hollowed interior of the plate-shaped main body 10′, the wires 40 are mutually insulated.

Referring to FIG. 5B, in one embodiment, filling material 50 fills up the gaps between the wires 40 and the hollowed interior of the plate-shaped main body 10′. In one embodiment, a plurality of lower contacts 22 are arranged on the lower surface of the plate-shaped main body 10′ and electrically connected with the wires 40 exposed on the lower surface.

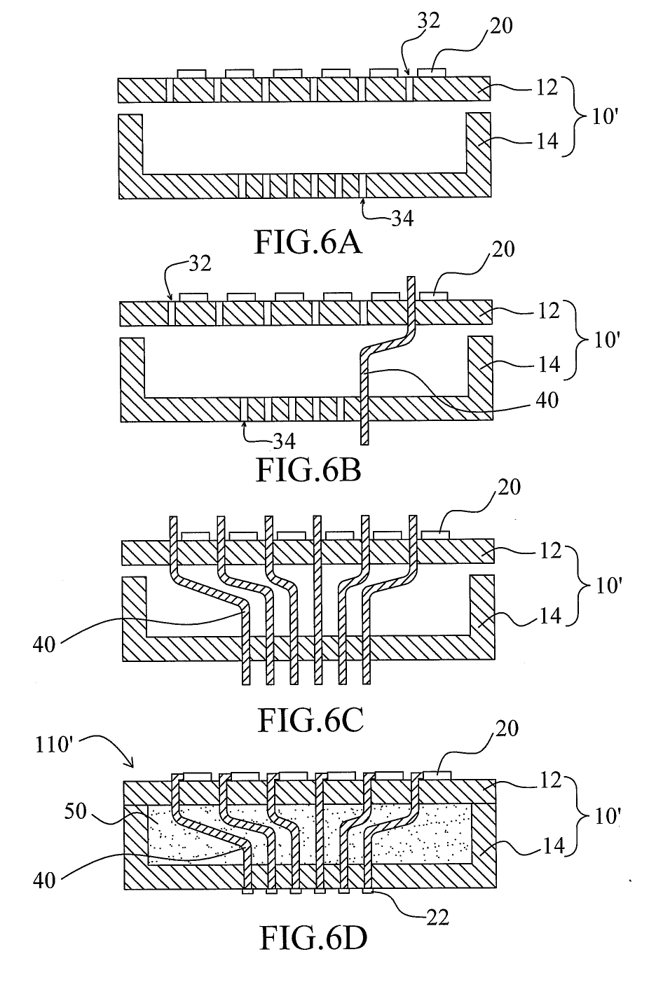

Referring to FIG. 6A, FIG. 6B, FIG. 6C and FIG. 6D, in one embodiment, the plate-shaped main body 10′ is formed with an assembly of a top cover 12 and a bottom cover 14. In one embodiment, the upper openings 32 are arranged in the top cover 12 and penetrate the top cover 12; the upper contacts 20 are arranged on the upper surface of the top cover 12, such as shown in FIG. 6A. The lower openings 34 are arranged in the bottom cover 14 and penetrate the bottom cover 14. Similarly, the pitch of the upper openings 32 is greater than the pitch of the lower openings 34 in this embodiment.

As shown in FIG. 6B, the size of the upper openings 32 and the size of the lower openings 34 are equal to the size of the wires 40. However, specific size of the openings is not demanded in the present invention as long as the wires can be inserted through and secured to the openings. As shown in FIG. 6C, two ends of each wire 40 are respectively inserted through the upper opening 32 and the lower opening 34. In the present invention, the pitch of the lower openings 43 is different from the pitch of the upper openings 32. The lower openings 34 having a smaller pitch can be fabricated with a hole-drilling technology.

Referring to FIG. 6C and FIG. 6D, after the wires 40 have been inserted through the openings, the redundant wires 40 are then removed. Next, the wires 40 exposed on the upper surface are electrically connected with the upper contacts 20. Next, the gaps between the wires and the hollowed interior of the plate-shaped main body 10′ may be filled up with filling material 50 if required. In one embodiment, the lower contacts 22 are arranged on the lower surface of the bottom cover 14 and electrically connected with the wires 40 exposed on the lower surface.

In the present invention, the main body may be made of ceramic material or material for circuit boards, such as FR-4, FR-5, or Bio-plastic(BP). The wires may be made of metallic material having high electric conductivity. Alternatively, an impedance coaxial cable can be used as the wires so as to reduce impedance and obtain guaranteed signal transmission quality.

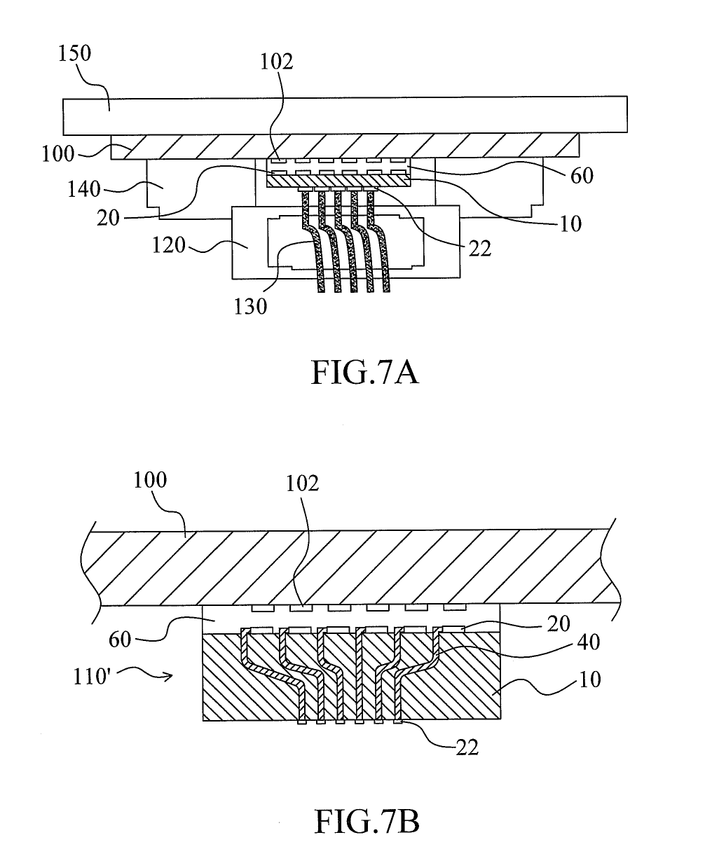

Refer to FIG. 7A and FIG. 7B, which are diagrams schematically show a circuit-test probe card according to one embodiment of the present invention. As shown in FIG. 7A, the circuit-test probe card utilizes the top surface and a bottom surface of a probe substrate 110′ to respectively electrically connect to a circuit board 100 and a plurality of probes 130.

Following, refer to FIG. 7B, which is a locally enlarged view of FIG. 7A. As shown in FIG. 7B, a plurality of upper contacts 20 are arranged on the upper surface of the main body 10. A plurality of wires 40 penetrates the main body 10. Two ends of each wire 40 are respectively exposed on the upper and lower surfaces of the substrate 10. The wires 40 are respectively electrically connected with the upper contacts 20. The pitch of the wires 40 exposed on the upper surface is greater than the pitch of the wires 40 exposed on the lower surface. In one embodiment, lower contacts 22 are arranged on the lower surface and respectively electrically connected with the wires 40. The lower contacts 22 are used to electrically connect with the probes 130 via mechanically contacting the wires 40 with the lower contacts 22 or soldering the wires 40 to the lower contacts 22, as shown in FIG. 7A.

Referring to FIG. 3A and FIG. 3B, in one embodiment, the main body 10 has a plurality of through-holes 30 penetrating the main body 10 from the lower surface to the upper surface and allowing the wires 40 to pass through the main body 10. In this embodiment, the pitch of the upper openings 32 of the through-holes 30 is greater than the pitch of the lower openings 34 of the through-holes 30. In one embodiment, the wires 40 protrudes from the upper openings 32 to electrically connect with the upper contacts 20, as shown in FIG. 3B. However, in another embodiment (not shown in the drawings), the wires 40 do not protrude from the upper surface but merely exposed by the upper openings 32. In such a case, the upper contacts 20 can be directly arranged on the positions where the wires 40 are exposed by the upper openings 32.

Referring to FIG. 5B, in one embodiment, the main body is a plate-shaped main body 10′ with a hollowed interior. In one embodiment, the gaps between the wires 40 and the hollowed interior are filled up with a filling material 50, and the plate-shaped main body 10′ includes a top cover 12 and a bottom cover 14, as shown in FIG. 6D.

Referring to FIG. 7A and FIG. 7B, in one embodiment, the probe substrate 110′ is joined to the circuit board 100 with anisotropic conductive film 60 (ACF). In another embodiment, a plurality of solder balls (not shown in the drawings) are arranged on the upper contacts 20 to electrically connect the upper contacts 20 with the circuit board 100.

In one embodiment, the main body or the plate-shaped main body can be formed with an assembly of a top cover and a bottom cover. The lower openings having small-pitch can be obtained via adopting appropriate material and using an appropriate drilling technology. The structural design of the present invention is sufficient to provide the openings having the arrangement of a small pitch. The person skilled in the art should understand that the technical focus of the present invention is on the different pitches of the openings of the upper and lower surfaces instead of the arrangements of the contacts of the upper and lower surfaces. The arrangements of the contacts of the upper and lower surfaces respectively depend on the arrangement of the contacts of the circuit board and the arrangement of the probes.

The present invention is characterized in the probe substrate effectively reducing the pitch from the scale of the circuit board to a fine pitch. For example, the pitch is reduced from millimeters to nanometers. Therefore, the structural design of the probe substrate of the present invention adapts to the persistently decreased pitch of the tested products and enables the probe card of the present invention to test products with decreased pitches of test points.

To sum up, the present invention provides a circuit-test probe card and a probe substrate structure that may effectively narrow down the pitch of testing points of the circuit-test probe card so as to match up the pitch variation of the tested products.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. A probe substrate, comprising:
a main body having a plurality of upper contacts on an upper surface thereof; and
a plurality of wires penetrating said main body, wherein two ends of each said wire are respectively exposed on said upper surface and a lower surface of said main body, a pitch of said wires exposed on said upper surface is greater than a pitch of said wires exposed on said lower surface, and said wires are respectively electrically connected with said upper contacts.

2. The probe substrate according to claim 1, wherein a plurality of through-holes penetrating said main body from said lower surface to said upper surface, said wires are respectively inserted through said through-holes, and a pitch of upper openings of said through-holes is greater than a pitch of lower openings of said through-holes.

3. The probe substrate according to claim 2, wherein said wires respectively protrude from said upper openings and are electrically connected with said upper contacts.

4. The probe substrate according to claim 1, further comprising a plurality of lower contacts arranged on said lower surface and respectively electrically connected with said wires.

5. A probe substrate, comprising:
a main body being plate-shaped and having a hollowed interior, wherein a plurality of upper contacts and upper openings are arranged on an upper surface of said main body, a plurality of lower openings are arranged on a lower surface of said main body, and a pitch of said upper openings is greater than a pitch of said lower openings; and
a plurality of wires, wherein two ends of each said wire respectively pass through said upper opening and said lower opening, said wires are mutually electrically insulated, and each said wire protrudes from one said upper opening and is electrically connected with one of said upper contacts adjacent to said upper opening.

6. The probe substrate according to claim 5 further comprising a filling material filling up gaps between said wires and said hollowed interior.

7. The probe substrate according to claim 5, wherein said main body further includes a plurality of lower contacts arranged on said lower surface and respectively electrically connected with said wires.

8. The probe substrate according to claim 5, wherein said main body is formed with an assembly of a top cover and a bottom cover.

9. A circuit-test probe card utilizing the top surface and the bottom surface of a probe substrate to respectively electrically connect with a circuit board and a plurality of probes is characterized in that said probe substrate, comprising:
a main body having a plurality of upper contacts on an upper surface thereof; and
a plurality of wires penetrating said main body, wherein two ends of each said wire are respectively exposed on said upper surface and a lower surface of said main body, and wherein a pitch of said wires exposed on said upper surface is greater than a pitch of said wires exposed on said lower surface, and wherein said wires are respectively electrically connected with said upper contacts.

10. The circuit-test probe card according to claim 9, wherein a plurality of through-holes penetrating said main body from said lower surface to said upper surface, wherein said wires are respectively inserted through said through-holes, and wherein a pitch of upper openings of said through-holes is greater than a pitch of lower openings of said through-holes.

11. The circuit-test probe card according to claim 10, wherein said wires respectively protrude from said upper openings and are electrically connected with said upper contacts.

12. The circuit-test probe card according to claim 9, further comprising a plurality of lower contacts arranged on said lower surface and respectively electrically connected with said wires.

13. The circuit-test probe card according to claim 9, wherein said main body is plate-shaped and has a hollowed interior.

14. The circuit-test probe card according to claim 13, further comprising a filling material filling up gaps between said wires and said hollowed interior.

15. The circuit-test probe card according to claim 13, wherein said main body is formed with an assembly of a top cover and a bottom cover.

16. The circuit-test probe card according to claim 9, further comprising a plurality of solder balls respectively arranged on said upper contacts to electrically connect said upper contacts with said circuit board.

17. The circuit-test probe card according to claim 9, further comprising an anisotropic conductive film arranged on said top surface of said probe substrate and configured for electrically connecting said upper contacts with said circuit board.
